(19) United States
(12) Patent Application Publication
(10) Pub. No.: US 2001/0024891 A1
(43) Pub. Date: Sep. 27, 2001

(54) Connector arrangement for an electro-luminescent lighting element and night light using such an arrangement

(76) Inventor: Tseng-Lu Chien, Taipei Hsien (TW)

Correspondence Address: HOWARD C. MISKIN, C/O STOLL, MISKIN, HOFFMAN & BADIE, EMPIRE STATE BUILDING, 350 FIFTH AVE., STE. 6110, NEW YORK, NY, 10118, US

(21) Appl. No.: 09/844,343

(22) Filed: Apr. 27, 2001

Related U.S. Application Data
(63) Continuation-in-part of application No. 09/373,614, filed on Aug. 13, 1999, now abandoned.
Application No. 09/373,614 is a continuation-in-part of application No. 08/383,404, filed on Feb. 3, 1995, now Pat. No. 5,667,394.

(51) Int. Cl. H01R 12/00; H05K 1/00

(52) U.S. Cl. 439/66

(57) ABSTRACT

Various electro-luminescent element lighting devices are disclosed all of which are easily assembled and accurately positioning so that all of the associated circuit components therein are arranged within the housing and without causing any damage to the components thereof.

This application is a continuation-in-part of U.S. patent application Ser. No. 09/373,614, which, in turn, is a continuation-in-part of allowed U.S. patent application Ser. No. 08/373,404, filed Feb. 3, 1995.

### BACKGROUND OF THE INVENTION

1. Field of the Invention

This invention relates to a connector arrangement for an EL lighting element, in which large area electrodes on the EL lighting element directly engage a specially designed connection member to facilitate electrical connection of the lighting element to a metal plug, thereby eliminating the need for conventional claw type or glue-type terminal arrangements, thereby simplifying assembly of the lighting element while reducing the risk of short circuits, electric shock, and sparking which could present a fire hazard. The invention also relates to an electro-luminescent lighting element for use in such a connector arrangement, and to a night light in which the connector arrangement is used.

2. Discussion of Related Art

The present invention utilizes the connector principles disclosed in parent application Ser. No. 08/383,404, but explicitly extends the concept to a variety of different types of electro-luminescent lighting element. Examples of EL lighting elements which may be used with the connector arrangement disclosed in the parent application and also disclosed herein are the electro-luminescent panels disclosed in U.S. Pat. No. 5,572,817, and in copending U.S. patent application Ser. Nos. 08/729,408 (now U.S. Pat. No. 5,752,337), 08/734,782 (now U.S. Pat. No. 5,833,508), and 08/746, 508 (now U.S. Pat. No. 5,794,366), each of which is incorporated by reference herein, as well as the three-dimensional electro-luminescent tube arrangement disclosed in U.S. patent application Ser. No. 08/758,393, filed Nov. 29, 1996 which is also incorporated by reference herein. The connector arrangement disclosed herein may also be used with the optical device disclosed in U.S. patent application Ser. No. 08/841,624 filed Apr. 30, 1997 also incorporated herein by reference, which is a continuation of U.S. patent application Ser. No. 08/489,160 (now abandoned).

In one aspect, the description of the invention contained herein is the same as that of the parent application, except that it is clarified that the connector can be used with a number of different lighting elements in that the lighting element itself is not limited to the particular “wire” and conductive member illustrated in the description of the preferred embodiment of the invention, and in that a detailed description of the night light utilizing the of the invention has been added.

Basically, the invention in one aspect, simplifies assembly of the connector by utilizing non-penetrative contact between wide area electrodes on the electro-luminescent element and a resilient conductive member. FIGS. 4, 5A, and 5B of parent U.S. patent application Ser. No. 08/383,404 show one example of a connector utilizing these principles, and FIGS. 1B-1D, 3A, and 3B of the parent application give one example of an electro-luminescent element, referred to in the parent application as an EL strip, which may be used in the connector utilizing the principles of the invention. However, while the lighting element shown in FIGS. 1B-1D, 3A, and 3B of the parent application is especially suitable for the use with the connector of FIGS. 4, 5A, and 5B of the parent application, as well as the arrangement illustrated in the present application, it will be appreciated by those skilled in the art that any electo-luminescent lighting element with appropriately configured electrodes, including those described in the above cited U.S. patent application Ser. Nos. 08/729,408, 08/734,872, 08/746,706, and 08/758,393.

The problems with prior electro-luminescent elements per se is described in detail in the parent application, and need not be repeated herein. Instead, the following discussion relates, in one aspect of the present invention, to the particular application of a night light, which particularly benefits from the principles disclosed in the parent application.

In particular, as shown in FIGS. 1 and 2, the conventional means for electrically connecting an electro-luminescent element 1 to a plug is to use claw-type metal terminals 2, the teeth 3 of which are designed to penetrate the surface of electrodes or contacts on the electro-luminescent element. In the case of a night-light, extensions 4 of these terminals are then connected to the prongs 5 extending through the housing 6 of a plug assembly arranged to be inserted into a wall outlet.

FIG. 3 shows an arrangement similar to that shown in FIGS. 1 and 2, with claw type terminals 7 extending from an electro-luminescent panel 8 attached to prongs 9 secured to the panel by double-sided tape 10 for use in a housing having a rear section 11, and a front section 12 having a window 13 through which the electro-luminescent panel 8 is visible to form the night light.

The problem with the use of claw type terminals, which are designed to push through the multiple layers of the electro-luminescent panel, is that the teeth on the terminals can easily cause damage to the panels during assembly, resulting in a high percentage of defective assemblies, and presenting a serious hazard of electrical shock. This is especially significant in the case of night lights, which are often placed in places where young children may have access to them.

This problem is solved in the parent application by establishing the electrical connection using a resilient conductive member to provide a self-biasing connection between connection wires and the large area terminals on the electro-luminescent element illustrated in the parent application. However, the concept of using a resilient or self-biased arrangement is not limited to the particular conductive member and wire arrangement described in the parent application, but rather can be applied in a wide variety of contexts to a wide variety of different types of electro-luminescent elements, and in the case of a night light greatly reduces the above-noted safety problem presented by claw type terminals, while actually simplifying assembly because the force necessary to cause penetration is not required.

In another aspect, which is of particular importance to the present invention, there remains a need to be filled so as to easily and accurately position the associated circuit components making up electro-luminescent lighting elements so that they are arranged in a desired manner. The positioning should be provided so that the electro-luminescent light element may be assemble in a snap like manner by compressing the associated elements, but without crushing or damaging any of the sensitive circuit components.

### SUMMARY OF THE INVENTION

It is accordingly an objective of the invention to provide an electro-luminescent element connector arrangement having simplified assembly and increased reliability, and which presents a reduced risk of sparking and causing a fire.

It is further objective of the invention to provide an electro-luminescent element connector arrangement having a reduced risk of short circuits and electric shock.

It is also an objective of the invention to provide a night light utilizing an electro-luminescent element connector arrangement having simplified assembly, increased reliability, and a reduced risk of short circuits and electric shock.

Moreover, is an objective of the present invention to provide for an electro-luminescent lighting device in which the associate circuit components are easily positioned so that the electro-luminescent elements may be easily assembled, but without crushing any sensitive element.

In addition, it is the objective of the present invention to provide for easy assembly of electro-luminescent lighting device comprised of multiple electro-luminescent lighting elements.

Some of these objectives of the invention are achieved, in accordance with the principles of one embodiment of the invention, by providing an electro-luminescent element connector arrangement in which an electrical connection between electrodes on the electro-luminescent element and a source of electric power are provided by a resilient conductive element which provides a self-biased electrical connection to the electrodes without the need for penetrative elements or movable elements.

The remaining objectives of the present invention are made available, in accordance with the principle of the preferred embodiment of the present invention, by providing an electro-luminescent lighting device comprised of the housing, at least one electro-luminescent element, a circuit board on which is mounted a circuit for controlling the electro-luminescent element and having cutouts therein, positioning means having a pair of prongs extending therefrom, and electrically conductive means for connecting to the prongs of the positioning means.

In the case of a night light, the objectives of the invention are achieved by providing an arrangement in which an electro-luminescent element used in the night light is connected to prongs extending from a housing of the night light by a resilient conductive members compressed between contact areas on the prongs and electrodes on the electro-luminescent element or between contact areas of a circuit board containing driver circuitry and the electrodes on the electro-luminescent element.

### BRIEF DESCRIPTION OF THE DRAWINGS

FIG. 1 is an exploded perspective view of a nigh light having a conventional construction.

FIG. 2 is a perspective view of a claw-type terminal for use in the night light of FIG. 1.

FIG. 3 is a perspective view of a portion of a variation of the night light of FIG. 1.

FIG. 4 is a perspective view of a housing for the night light of FIG. 3.

FIG. 5 is an exploded perspective view of a night-light constructed in accordance with the principles of a preferred embodiment of the invention.

FIG. 6 is an exploded perspective view of a variation of the night light of FIG. 5.

FIG. 7 is an exploded perspective view of an electro-luminescent light assembly suitable for use in the night lights of FIGS. 5 and 6.

FIG. 8 is an exploded perspective view of a further variation of the night-lights illustrated In FIGS. 5 and 6.

FIG. 9 is a perspective view of an assembled night-light corresponding to the night-lights illustrated in FIGS. 5 and 8.

FIG. 10 is a perspective view of an assembled night light corresponding to the night light of FIG. 6.

FIGS. 11 and 12 are, respectively, a plain view of an electro-luminescent element suitable for use in connection with the preferred embodiment of the invention, and an end view of the electro-luminescent element shown in FIG. 11.

FIG. 13 is an exploded perspective view illustrating one embodiment of an easily assembled electro-luminescent lighting device of the present invention.

FIG. 14 illustrates the different resilient conductive members that may be used in the practice of the present invention.

FIG. 15 is an exploded perspective view of another embodiment of a electro-luminescent lighting device of the present invention.

FIG. 16 is an exploded perspective view of an additional electro-luminescent lighting device of the present invention.

FIG. 17 is a exploded perspective view of a still further embodiment of the present invention.

FIG. 18. illustrates an electro-luminescent panel having multiple lighted areas.

### DETAILED DESCRIPTION OF THE PREFERRED EMBODIMENTS

As illustrated in FIG. 5, a night light constructed in accordance with the principles of a preferred embodiment of the invention includes an electro-luminescent element 14, including multiple phosphor segments 15 and electrode contact areas 16(which are actually on the rear side of elements 16 extending from panel 14). The housing for the night light includes a rear section 17 containing an indentation for receiving the electro-luminescent element 14 and openings 19 for prongs 19, and a front section 20 having an opening or window 21 through which the electro-luminescent element is to be viewed. An optional frontsheet 22 may be positioned between the electro-luminescent element 14 and window 21.

In order to greatly simplify assembly of the night light of FIG. 5, contact areas 16 and prongs 19 are electrically connected together by means of resilient conductive elements 23 which are compressed between the contact areas and prongs when the housing is being assembled together. Compression of the conductive elements 23 ensures that electrical continuity between the electrodes of the electro-luminescent elements and the prongs is maintained, with the resilience of the conductive elements also compensating for tolerances in the construction of the prongs or contact areas of the electrodes of the electro-luminescent element, for example in the case where the prongs and electrodes have facing surfaces that are not completely parallel to each other, or not completely flat.

The conductive elements 23 may be in the form of flexible or elastic conductive rubber elements, or conductive elements of similarly flexible and conductive plastic or metal material. Prongs 19 are UL-listed standard plugs, or equivalent plugs arranged to meet the requirements of countries other than the United States.

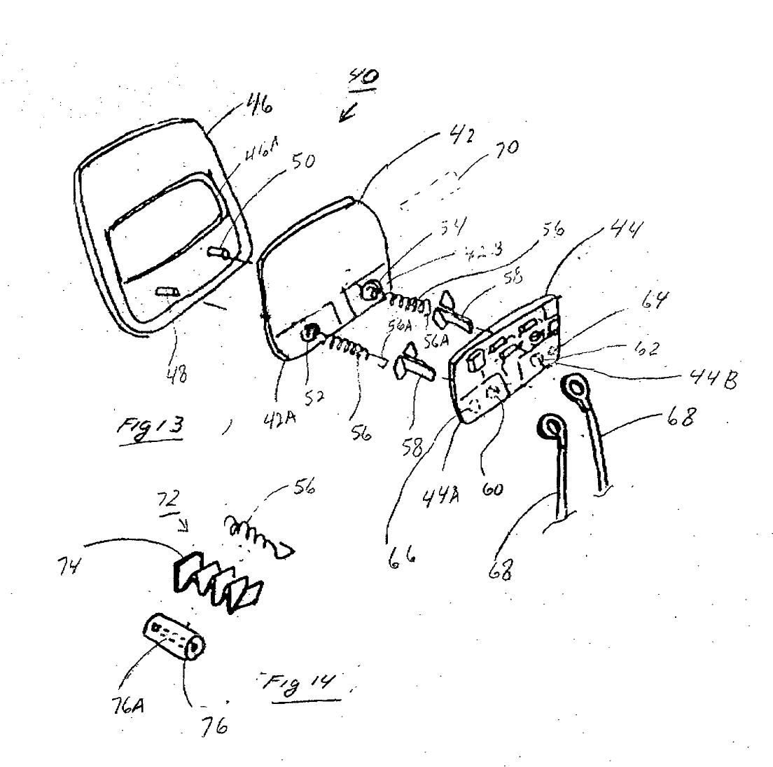

Preferably, rear housing section 17 and front housing section 20 are sealed together to prevent the night light from being opened and the electrical connections exposed. The indentation in which the electro-luminescent element is received may of course have any desired configuration, or may be eliminated in favor of alternative electro-luminescent element holding means, and the means by which the housing sections are held together and/or sealed may include suitable holding or sealing means, including glue, double-sided tape, press-fit posts, screws, melting, ultra-sonic sealing, hot melt adhesives, etc., resulting in an attractive and compact night light assembly similar to the one illustrated in FIG. 9.

The electro-luminescent panel 14 may be of the type disclosed in U.S. Pat. No. 5,572,817 and copending U.S. patent application Ser. Nos. 08/729,408, 08/734,872, and 08/746,706, in which attractive designs are obtained by including logos, figures, cartoon characters, words, on either the front sheet 22 or the electro-luminescent element itself, either by printing, silk-screening, stenciling, or the like, and/or by appropriately arranging the phosphor segments of the electro-luminescent element. Alternatively, or in addition to electro-luminescent panel 14, the night light may include a three-dimensional tube 14′ arranged in an attractive pattern in the manner described in copending U.S. patent application Ser. No. 08/758,393. In the embodiment illustrated in FIG. 8, for example, a single color panel 14″ provides background for the illumination effect provided by the three-dimensional electro-luminescent element 14′, the other elements of the night light being the same as described in connection with FIG. 5, except that additional conductive resilient elements, for example having the configuration illustrated in parent U.S. patent application Ser. No. 08/383,404, must be included in order to provide the necessary electrical connection. Further details of either the electro-luminescent element may be found in the above-cited patent and patent applications.

While in the arrangement of FIG. 5, the electro-luminescent panel is directly connected to the prongs of the night light outlet, it is also within the scope of the invention to use conductive member(s) 23′ to connect one or more electrodes of the panel to an inverter, control circuit, function interface, or the like, which can be the form of a conventional circuit or an integrated circuit. Numerous suitable circuits are known and it is intended that the invention encompass any circuitry to which the electro-luminescent element might be connected, or no circuitry at all, with the electrodes of the electro-luminescent element being directly and exclusively connected to the prongs of the night light. By circuitry is meant any electrical component, including wires, resistors, capacitors, transistors, inductors, and so forth, as well as switches such as the illustrated photo-sensor 27.

As shown in FIGS. 6 and 10, for example, the additional circuitry might be housed in an extension 26 of the rear housing member 25. FIG. 6 also illustrates the variation in which the electro-luminescent element 26 does not have multiple segments, the decorative pattern being obtained instead by appropriate decoration of the frontsheet 27.

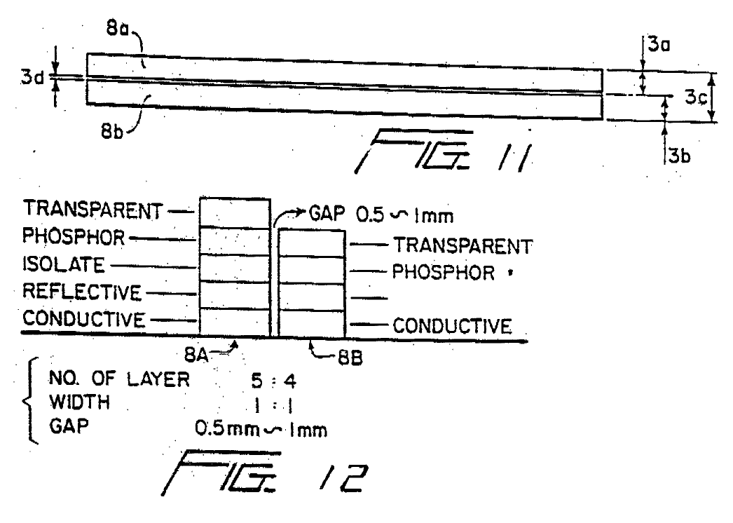

Alternatively, in the variation shown in FIG. 7, the effects obtained by electro-luminescent element 28 and frontsheet 29 are enhanced by including an optical effects device 30 similar to the one described in copending U.S. patent application Ser. No. 08/841,624 and its parent U.S. patent application Ser. No. 08/489,160, in which the image of the electro-luminescent element is enhanced by passage through a transparent transmission medium such as water, a gel, a solid transparent medium, epoxy, silicone, PVC, PC, acrylic, or the like to increase the apparent brightness of the element. The optical device can form a convex or concave lens, and can magnify the image, change the image location, change the focus, or change the color of emitted light in a simple and inexpensive yet effective manner.

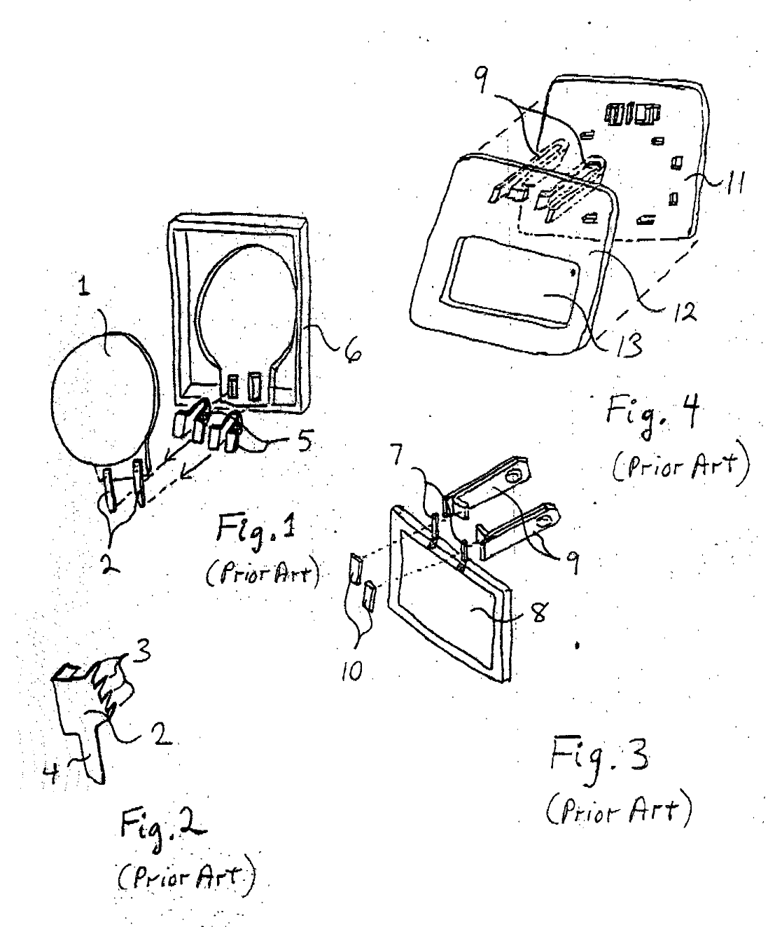

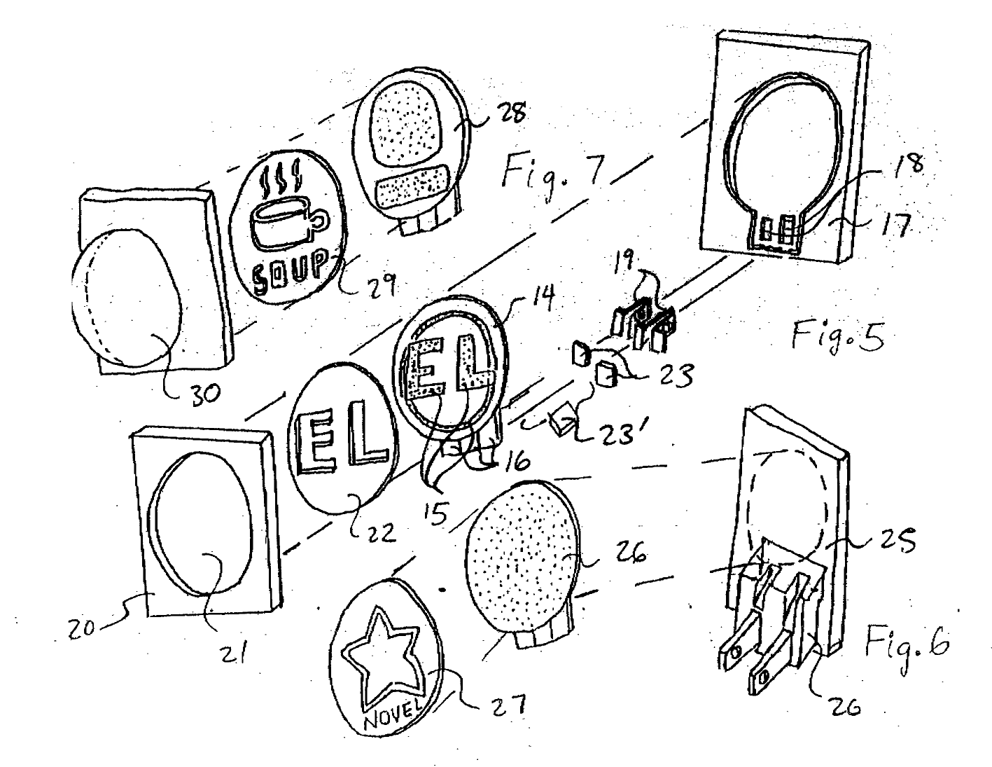

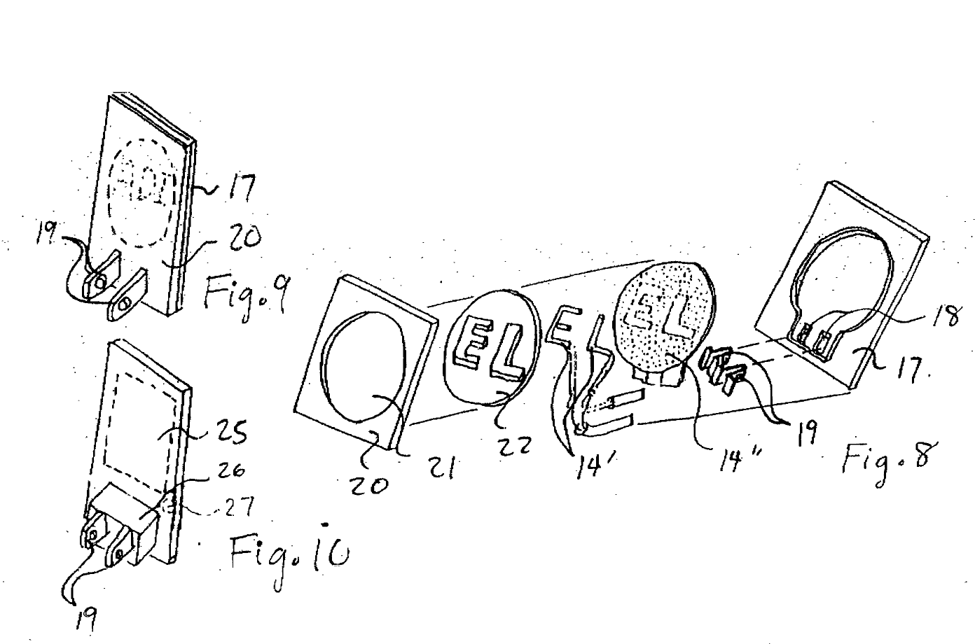

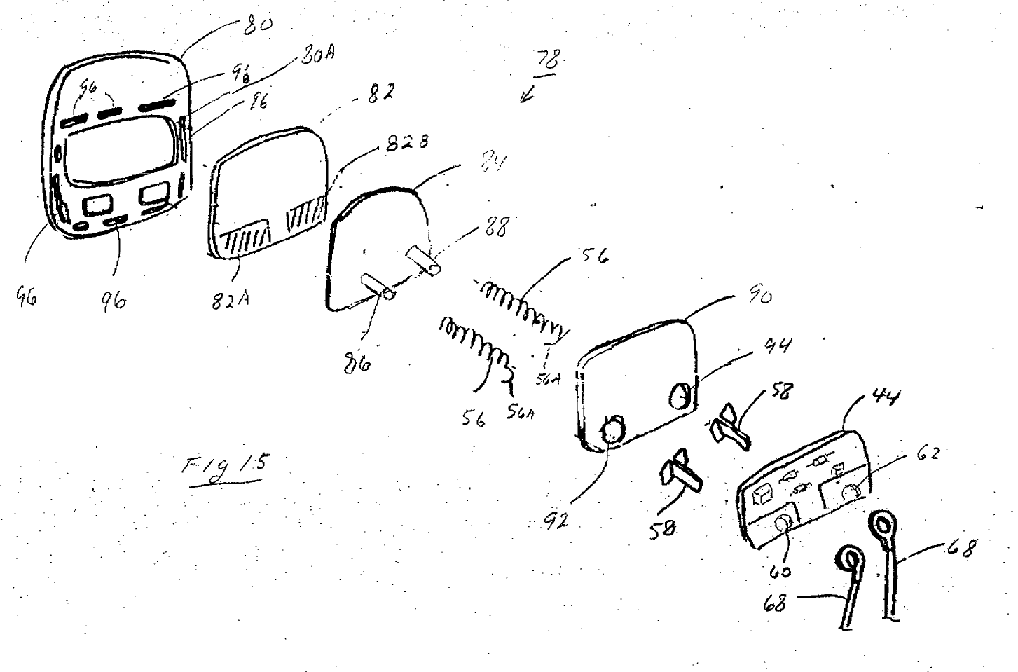

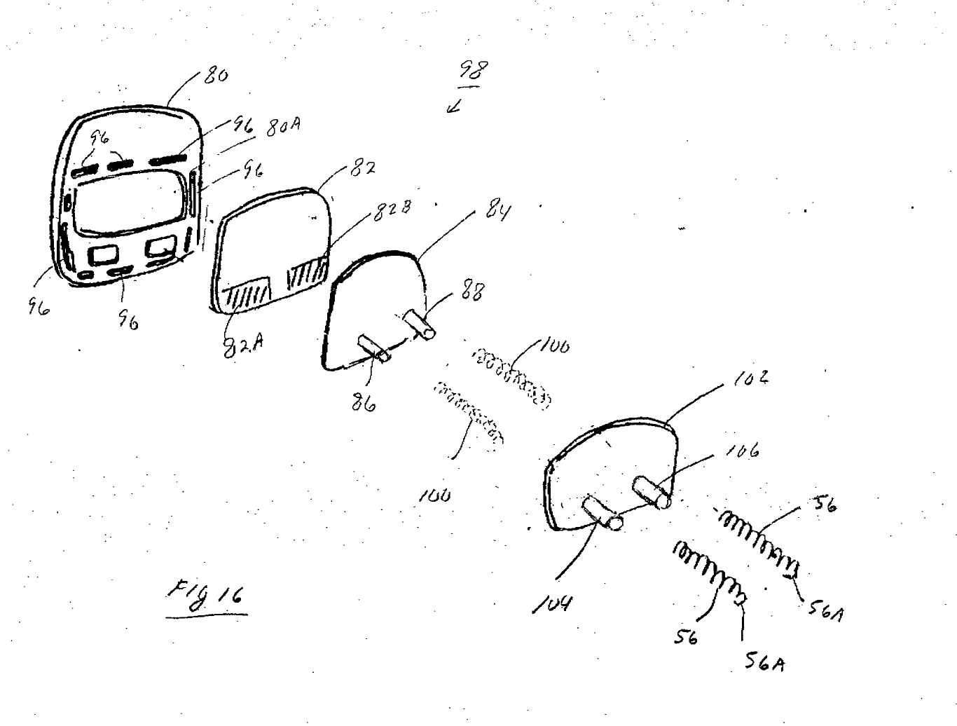

Finally, FIGS. 11 and 12, which are identical to FIGS. 3A and 3B of the parent application, show and electro-luminescent element made up of two parallel EL strip halves 8A and 8B. EL strip half 8A consists of, in order from top to bottom, a transparent conductive layer, a phosphor layer, an isolation layer, a reflective layer, and a conductive layer, while EL strip half 8B consists of, in order from top to bottom, a transparent conductive layer, a phosphor layer, an isolation layer, and a conductive layer. Each of the layers is per se identical to corresponding layers in conventional EL strips, except that in transparent conductive layer does not include an extra-width section of the type discussed in the parent application in connection with the prior art. Unlike the conventional EL strip shown in FIGS. 1A-1D of the parent application, however, electrical connection to the EL strip of the preferred embodiment is accomplished by simply establishing a direct electrical connection to the EL strip of the preferred embodiment with the respective lowermost conductive layers of the two EL strip halves, with one of the conductive layers serving as the low voltage connection and the other as the high voltage connection, and thus this strip is especially suitable for use in connection with the night lights illustrated in FIGS. 4-10.

Another aspect which is of primary importance to the present invention may be further described with reference to FIGS. 14-18 that illustrate various embodiments of electro-luminescent lighting devices having one or more electro-luminescent elements along with the circuit components and all of which are easily assembled in a quick and accurate manner.

FIG. 14 illustrates an electro-luminescent lighting device 40 comprised of an electro-luminescent element 42 having electrodes 42A and 42B, a circuit board 44, and a housing 46.

The electro-luminescent element 42, as well as other electro-luminescent elements to be described may be selected from the group consisting of non-organic electro-luminescent elements, organic electro-luminescent elements, and various combinations thereof. Further, electro-luminescent elements may comprise one or more lighted areas.

The circuit board 44 has mounted thereon associated circuit components so as to form a control circuit for the electro-luminescent element. The control circuit may be selected so a to provide various illumination patterns generated by the electro-luminescent element 42 in a manner known in the art.

The housing 46 has a window 46A through which the illumination generated by the electro-luminescent element 42. The housing further includes post 48 and 50 which are dimensioned so as to pass through openings 52 and 54, respectively of the electro-luminescent element 42.

The post 48 and 50 further accommodate metal springs 56 having looped ends 56A. The looped ends 56A are dimensioned so as be inserted into openings of clips 58.

The clips 58 are dimensioned so as to be insertable into openings 60 and 62 of the circuit board 44. The circuit board 44 may further have openings 64 and 66, shown in phantom. The clips 58 insertable into holes 60 and 62 are connectable to conductors 68 which conduct the output of the circuit board to an external circuit.

The electro-luminescent element 42, in particular the electrodes 42A and 42B, may be secured relative to the cutouts 52 and 54 by the use of a double-sided adhesive tape or by glue or adhesive.

The lighting device 40 may be easily assembled by first inserting the post 48 and 50 into the openings 52 and 54 respectively and then placing the metal springs 56 over the posts 48 and 50, while at the same time inserting the ends 56A into the clips 58 which, in turn, are inserted into openings 60 and 62 which, in turn, are connected to conductors 68 by appropriate means.

Once the parts are interconnected, the arrangement may be cured by the use of conventional means, such as screws, rivets, hot melting, or other conventional securing means. The different types of resilient conductive means may be further described with reference to FIG. 14.

FIG. 14 illustrates the metal spring 56, as well as a metal plate 74 and a rubberized member 76 carrying and electrically conductive member 76A.

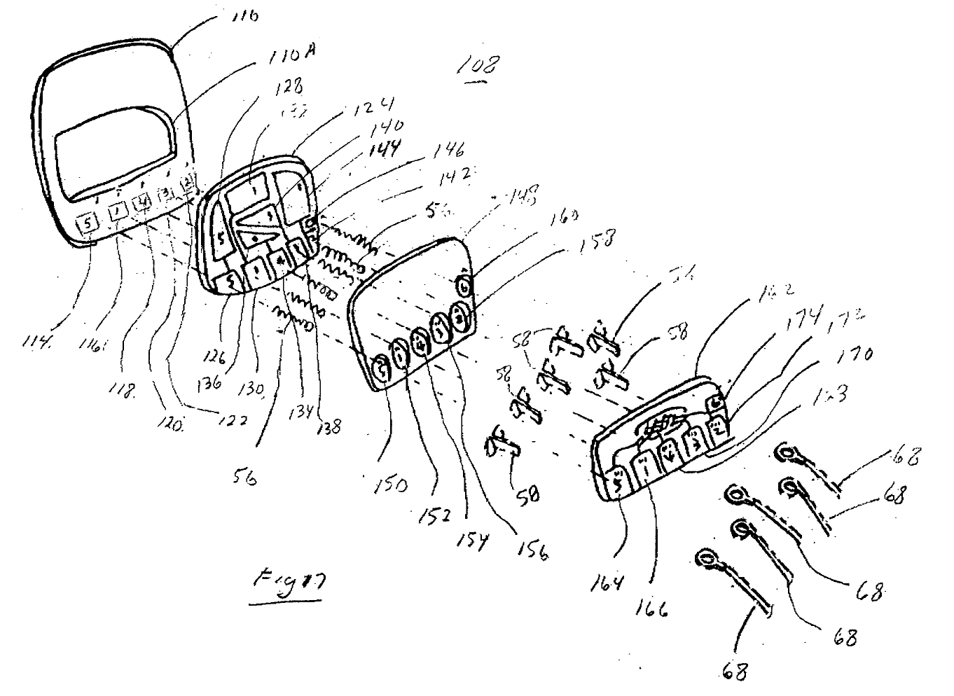

FIG. 15 is a exploded perspective view of another embodiment 78 of an electro-luminescent lighting device. The electro-luminescent lighting device 78 comprises a housing 80, an electro-luminescent element 82 having electrodes 82A and 82B, a positioning member 84 having posts 86 and 88, metal springs 56, an interplate 90, having openings 92 and 94, the clips 58, the circuit board 44, and the electrical conductors 88.

The housing 80 has a window 88 that allows for the light generated by the elector-luminescent element 82 to be emitted therefrom. The housing 80 further has ledges 96 which are arranged thereon so as to provide for a shelf for lodging the electro-luminescent element 82.

The electro-luminescent lighting device 78 is assembled by placing the electro-luminescent element 82 onto the shelves 96 and then placing the positioning member 84 against the lodged electro-luminescent element 82. The metal springs 56 are then placed onto the posts 86 and 88 of the positioning member 84 and then the posts 86 and 88 are inserted into the openings 92 and 94 respectively, of the interplate 90. Then the looped ends 56A are inserted into the clips 58 which, in turn, are inserted into the openings 60 and 62 which, in turn, allow for the signal conductors 68 to be connected to the clips 58 in a manner as previously described.

FIG. 16 is a exploded perspective view of electro-luminescent lighting device 98 comprised of the housing 80, the electro-luminescent element 82, the positioning means 84, preferably metal springs 100, a second positioning member 102 having cylindrical posts 104 and 106 each having a retaining cavities, and the metal spring 56.

The electro-luminescent lighting device 98 is assembled by first placing the electro-luminescent element 82 and the first positioning member 84 onto the ledges 96 of the housing 80 in a manner as previously described with reference to FIG. 15. The springs 100, shown in phantom, are preferably placed over the posts 86 and 88 which, in turn are then assembled into the posts 104 and 106 respectively, more particularly, into the internal cavities of posts 104 and 106. The springs 56 are then insertable onto the posts 104 and 106.

The second positioning member 102 may be part of a additional housing, whereas, the springs 56 may be interconnected to clips 56 which, in turn, may be connected to a circuit board 44 so that the circuit board 44 in one housing may be used to service the electro-luminescent element 82 within another element. Further, the shelves 96 may be arranged so that the electro-luminescent element 82, as well as the first positioning member 84, may be connected in a snap-lock manner.

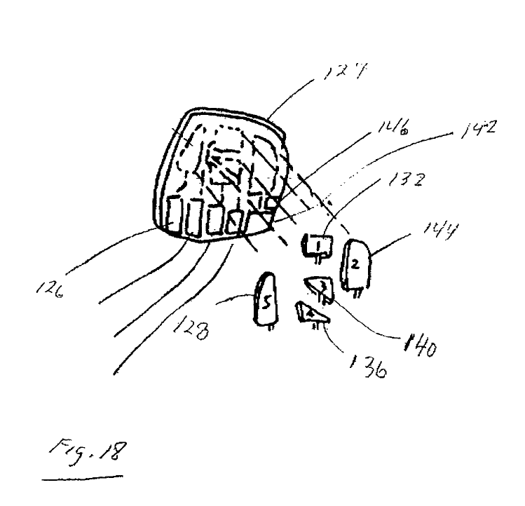

FIG. 17 illustrates a electro-luminescent lighting device 108 having a housing 110 with a window 110A. The housing further comprises transparent regions 114, 116, 118, 120 and 122.

The electro-luminescent lighting device 108 further comprises an electro-luminescent element 124. The electro-luminescent element 124 comprises a conductive pad 126 which is electrically connected to a electro-luminescent lighting area 128, a pad 130 which is electrically connected to an electro-luminescent lighting element 132, a electrically conductive pad 134 which is electrically connected to a lightable area 136, an electrical pad 138, which is electrically connected to an electro-luminescent element 140, an electrically conductive pad 142 which is electrically connected to an electro-luminescent element 144, and a pad 146 which serves as a ground connector for the electro-luminescent element 124. Pads 126, 130, 134, 138, 142, and 146, mate with the electrically conducted metal spring 56.

The electro-luminescent lighting device 108 further comprises an inner housing 148 having openings 150, 152, 154, 156, 158, and 160. The electro-luminescent element 108 further comprises a circuit board 162 having conductive pads 164, 166, 168, 170, 172, and 174. The electro-luminescent element 108 may in one embodiment thereof also include the clips 58 and the conductors 68, both shown in phantom.

The electro-luminescent lighting device 108 in one embodiment, without the clips 58 and the conductor 68 dissemble by compressing together the elements 110, 124, 148 and 162 so that the electrically conductive pads of elements 124 and 162 are in alignment with the transparent regions 114, 116, 118, 120 and 122 of the housing 110. For example, the transparent region 114 carrying the number 5, is aligned with the conductive pad 126 carrying the number 5 and in contact with the associated spring metal member 56 which passes through the opening 150 carrying the number 5 which, in turn, allows that associated spring 56 to come into contact with the conductive pad 164 of the circuit board 162. Once these members are compressed together, they may be fixed in place by the use of an appropriate adhesive.

In another embodiment of the electro-luminescent lighting device 108, the clips 58 are connected to the associated metal spring 56 and inserted through the conductive pads 164, 166, 168, 170, 172 provided with an appropriate opening (not shown) so as to be connected to the electrical conductors 68.

FIG. 18 illustrates further details of the electro-luminescent element 124 having multiple electro-luminescent sub-elements 128, 132, 126, 140 and 144.

It should now be appreciated that the practice of the present invention provides for various embodiments of electro-luminescent lighting devices containing one or more electro-luminescent elements and all of which are easily assembled without causing any damage to any of the associated circuit components.

Having thus described a preferred embodiment of the invention and a number of different variations and modifications of the preferred embodiment, it is anticipated that still further variations and modifications will undoubtedly occur to those skilled in the art upon reading the above description, and it is therefore intended that the invention be interpreted solely in accordance with the appended claims.

I claim:

1. A connecting arrangement for an electro-luminescent light element(s) comprising:
Means for positioning an electro-luminescent element(s);
Means for positioning circuit signal end(s);
Means for positioning at least one of compressible contacts relative to both the Electro-luminescent element(s) and circuit-signal end(s); and
The first and second members which form a means for compressing the contacts against electrodes(s) of the electro-luminescent element(s) and against the circuit-signal end(s) to establish an electrical connection between the circuit-signal end(s) and the electro-luminescent element(s).
The improvement including the said signal-end(s) is away from circuit board selected from group combination from Flexible Printing circuit (FPC), wire harness, silver past, conductive ink, conductive layer, conductive material.

2. A connector arrangement as claimed in claim 1 wherein the contacts are cylinder conductive device may selected from group combination from metal spring, metal plastic, rubber contact.

3. A connector arrangement as claimed in claim 2, wherein the positioning means for the contact comprising a pair of post (or tunnel) in one of said member, the means for positioning the Electro-luminescent element(s) comprises a cut-out in the Electro-luminescent element(s), and the means for the circuit-signal end(s) are well designed on a circuit board.

4. A connector arrangement as claimed in claim 3, wherein the member is secured by means selected from group combination of snapping, ultrasonic, screw, rivet, melting, press-tighten, or conventional secured means.

5. A connector arrangement as claimed in claim 3, wherein the means for positioning the Electro-luminescent element(s) comprises a fixing means my selected from group combination including post, wall, recess, groove, opening, tape, glue, or equivalent procedures.

6. A connector arrangement as claimed in claim 5, the said Electro-luminescent element is secured in the cutout by means of double-sided tape.

7. A connector arrangement as claimed in claim 1, wherein the means for positioning the Electro-Luminescent element comprises a inner housing with cut-out, channel, tunnel to allow the contacts can passing through to make current delivery.

8. A connector arrangement as claimed in claim 1, the said Electro-Luminescent element is secured by inner housing.

9. A connector arrangement as claimed in claim 1, the said circuit board on which are mounted components of a control circuit for the Electro-Luminescent element(s).

10. A connector arrangement as claimed in claim 1, the said Electro-Luminescent element(s) may be selected from group combination from non-organic Electro-luminescent element(s), organic Electro-Luminescent element(s) for geography configuration.

11. A connector arrangement as claimed in claim 1, the said Electro-Luminescent element(s) further comprises plurality of lit-area(s) to form the said element(s) which having multiple terminals, each one of said lit-area having individual electrode, and wherein the said member includes both said means for positioning said current -signal end(s) and said means for positioning said compressible contacts, with one of said current-signal end and one of said contacts being provided for each of said lit-area.

12. A connector arrangement as claimed in claim 11, the said plurality of lit-area(s) may have different colors, size, indicia, brightness, stencil, design.

13. A connector arrangement as claimed in claim 1, further comprising means for positioning additional Electro-Luminescent element(s) , means for positioning a additional current-signal end(s) relatively, and means for positioning a additional compressible contacts relative to said Electro-luminescent element(s) and said additional current signal end(s).

14. A connector arrangement as claimed in claim 13, wherein said Electro-luminescent element(s) and current-signal end(s) are positioned at a non-zero angle relative to each other so can make a curved light device.

15. A connector arrangement as claimed in claim 14, the said the Electro-luminescent element(s) are of different colors.

16. A connector arrangement as claimed in claim 1, further comprising a glue-means applied on an apparatus to which the element(s) is to be attached.

17. A connector arrangement as claimed in claim 1, the said member comprises a plurality of each of said positioning means to allow the connector set to be used with a plurality of different Electro-Luminescent element(s) configuration.
